(19) United States
(12) Patent Application Publication
(10) Pub. No.: US 2016/0190415 A1
(43) Pub. Date: Jun. 30, 2016

(54) LIGHT EMITTING DEVICE PACKAGE

(71) Applicant: Myoung Bo PARK, Suwon-si (KR)

(72) Inventor: Myoung Bo PARK, Suwon-si (KR)

(21) Appl. No.: 14/981,879

(22) Filed: Dec. 28, 2015

(30) Foreign Application Priority Data
Dec. 26, 2014 (KR) 10-2014-0190520

(51) Int. Cl. H01L 33/62; H01L 33/50; H01L 33/56

(52) U.S. Cl. CPC H01L 33/62; H01L 33/56; H01L 33/507

(57) ABSTRACT

A light emitting device package may include a package body; first and second lead frames; and a support part disposed below the first and second lead frames and having a region overlapping with at least a portion of a space formed between the first and second lead frames, the support part containing a material different from that of the package body.

### CROSS-REFERENCE TO RELATED APPLICATION

This application claims the priority and benefit of Korean Patent Application No. 10-2014-0190520 filed on Dec. 26, 2014, with the Korean Intellectual Property Office, the disclosure of which is incorporated herein by reference.

### BACKGROUND

Embodiments relate to a light emitting device package.

In general, light emitting device packages, light sources including semiconductor light emitting devices such as light emitting diodes (LEDs), may be applied to various types of lighting devices, the backlight units of display devices, automobile headlamps, and the like. A light emitting device package, a semiconductor package including a light emitting device, may include a light emitting device provided as a light source, a package body receiving the light emitting device therein, lead frames coupled to the package body and transferring an external electrical signal to the light emitting device, and the like.

In general, a light emitting device included in a light emitting device package may include a first electrode and a second electrode respectively connected to different lead frames. Thus, the lead frames coupled to the package body may also have first and second lead frames electrically separated from each other and transferring different electrical signals to the first and second electrodes. In the case of applying force to the light emitting device package from the outside of a package body or applying stress to the light emitting device package due to heat generated in the light emitting device or the like, the force or stress may be concentrated on a space between the first and second lead frames, such that the light emitting device package may be damaged or broken.

### SUMMARY

An embodiment includes a light emitting device package including a package body; first and second lead frames; and a support part disposed below the first and second lead frames and having a region overlapping with at least a portion of a space formed between the first and second lead frames, the support part containing a material different from that of the package body.

An embodiment includes a light emitting device package comprising: a package body; a pair of lead frames disposed in the package body and electrically isolated from each other; and a support part; wherein the pair of lead frames have a receiving space adjacent to a space formed between the pair of lead frames, and the support part is disposed within the receiving space.

An embodiment includes a light emitting device package comprising: a package body; first and second lead frames disposed in the package body and electrically isolated from each other; a light emitting device disposed on the first and second lead frames; and a support part disposed on a side of the first and second lead frames opposite to the light emitting device, extending across a separation space between the first and second lead frames, and containing a material different from that of the package body.

### BRIEF DESCRIPTION OF DRAWINGS

The above and other aspects, features and advantages will be more clearly understood from the following detailed description taken in conjunction with the accompanying drawings, in which:

FIG. 1 is a perspective view illustrating a light emitting device package according to an embodiment;

FIG. 2 is a cross-sectional view illustrating a cross-section of the light emitting device package illustrated in FIG. 1, taken along line A-A′;

FIG. 3 through FIG. 5D are cross-sectional views of light emitting device packages according to various embodiments;

FIG. 6 is a perspective view illustrating a light emitting device package according to another embodiment;

FIG. 7 is a cross-sectional view illustrating a cross-section of the light emitting device package illustrated in FIG. 6, taken along line B-B′;

FIG. 8 is a cross-sectional view illustrating a light emitting device package according to another embodiment;

FIG. 9 through FIG. 11 are plan views respectively illustrating a light emitting device package according to various embodiments;

FIG. 12a through FIG. 12d are views illustrating a method of manufacturing the light emitting device package according to an embodiment;

FIG. 13a through FIG. 13d are views illustrating a method of manufacturing the light emitting device package according to another embodiment;

FIG. 14a through FIG. 14d are views illustrating a method of manufacturing the light emitting device package according to another embodiment;

FIG. 15 through FIG. 20 are views illustrating light emitting devices applicable to the light emitting device package according to various embodiments;

FIG. 21 and FIG. 22 are views illustrating examples of backlight units including a light emitting device package according to an embodiment;

FIG. 23 is a view illustrating an example of a lighting device including a light emitting device package according to an embodiment; and

FIG. 24 is a view illustrating an example of a headlamp including a light emitting device package according to an embodiment.

### DETAILED DESCRIPTION

Various embodiments will now be described more fully with reference to the accompanying drawings in which some embodiments are shown. Embodiments may, however, take many different forms and should not be construed as limited to the embodiments set forth herein. Rather, these embodiments are provided so that this disclosure is thorough and complete and fully conveys the scope to those skilled in the art. In the drawings, the sizes and relative sizes of layers and regions may be exaggerated for clarity, and the same reference numerals will be used throughout to designate the same or like elements.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Spatially relative terms, such as “beneath,” “below,” “lower,” “above,” “upper” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Meanwhile, when an embodiment can be implemented differently, functions or operations described in a particular block may occur in a different way from a flow described in the flowchart. For example, two consecutive blocks may be performed simultaneously, or the blocks may be performed in reverse according to related functions or operations.

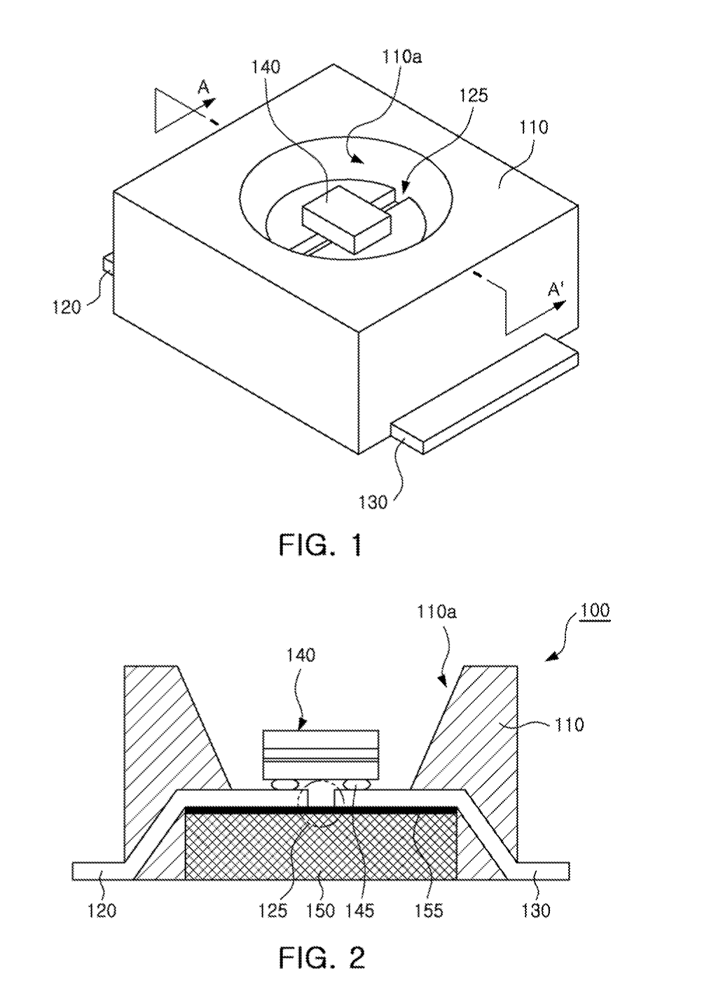

FIG. 1 is a perspective view illustrating a light emitting device package according to an embodiment. Referring to FIG. 1, a light emitting device package 100 according to an embodiment may include a package body 110, first and second lead frames 120 and 130 provided in the package body 110, and a light emitting device 140. The package body 110 may have a mounting space 110a and the light emitting device 140 may be disposed in the mounting space 110a. At least portions of surfaces of the first and second lead frames 120 and 130 may be exposed in the mounting space 110a, and the light emitting device 140 may be disposed on the exposed portions of the surfaces of the first and second lead frames 120 and 130 exposed within the mounting space 110a. The light emitting device 140 may be electrically connected to the first and second lead frames 120 and 130. Although the mounting space 110a is defined as a recessed region of the package body 110 in FIG. 1, it may be defined as a region different therefrom. In another embodiment, the package body 110 may have a generally flat, upper surface, and the light emitting device 140 may be mounted on the lead frames 120 and 130 exposed at the flat upper surface of the package body 110. In some embodiments, an encapsulant, a lens, or the like may be further prepared on the flat upper surface of the package body 110.

Portions of the first and second lead frames 120 and 130 may protrude outwardly from the package body 110 as illustrated in FIG. 1. Although FIG. 1 illustrates a case in which the first and second lead frames 120 and 130 are protrude outwardly from two surfaces of the package body 110 opposed to each other, the first and second lead frames 120 and 130 may be modified in different forms. For example, the first and second lead frames 120 and 130 may be bent along exterior surfaces of the package body 110 and may protrude from a lower surface of the package body 110. Portions of the first and second lead frames 120 and 130 protruding outwardly from the package body 110 may be electrically connected to an external circuit board or the like.

The light emitting device 140 may be a semiconductor light emitting device and may be a light emitting diode (LED) configured to emit light due to the recombination of electrons and holes. The light emitting device 140 may include first and second conductivity-type semiconductor layers and an active layer interposed between the first and second conductivity-type semiconductor layers. A phenomenon in which electrons and holes within the active layer are recombined with each other through an electrical signal being transferred through the first and second lead frames 120 and 130 may occur, thereby leading the generation of light.

Since the first and second lead frames 120 and 130 may be configured to supply the light emitting device 140 with different electrical signals, they may be electrically separated from each other. As illustrated in FIG. 1, a predetermined separation space 125 may be provided between the first and second lead frames 120 and 130.

In particular, in the case of a flip-chip structure in which the light emitting device 140 is mounted on the first and second lead frames 120 and 130 through solder bumps, the separation space 125 between the first and second lead frames 120 and 130 may be disposed below the light emitting device 140 as illustrated in FIG. 1. Thus, when external force is applied to the package body 110, solder bumps provided between the light emitting device 140 and the first and second lead frames 120 and 130 may be damaged due to external force concentrated on the separation space 125. In addition, thermal stress caused by heat generated from or conducted through the first and second lead frames 120 and 130 may be concentrated on the solder bumps provided between the light emitting device 140 and the first and second lead frames 120 and 130, whereby the solder bumps may be damaged.

As will be described in further detail below, the light emitting device package 100 and, in particular, the package body 110, according to an embodiment may include a support part that may reduce and/or eliminate such effects from external forces, thermal stress, or the like.

FIG. 2 is a cross-sectional view illustrating a cross-section of the light emitting device package illustrated in FIG. 1, taken along line A-A′. Referring to FIG. 2, the light emitting device package 100 according to the embodiment may include the package body 110, the first and second lead frames 120 and 130, the light emitting device 140 and the like. The light emitting device 140 may be mounted on the first and second lead frames 120 and 130 through solder bumps 145. The first and second lead frames 120 and 130 may be configured to apply different electrical signals to the first and second conductivity-type semiconductor layers included in the light emitting device 140. Thus, the predetermined separation space 125 may be provided between the first and second lead frames 120 and 130.

When external force is applied to the package body 110 or heat is generated due to a light emission operation of the light emitting device 140, thermal stress caused by the external force or heat may be concentrated on the separation space 125 between the first and second lead frames 120 and 130. In particular, in the case that the light emitting device 140 is mounted on the first and second lead frames 120 and 130 by the solder bumps 145, at least a portion of the separation space 125 may be positioned below the light emitting device 140, and thermal stress may be concentrated on the separation space 125 to cause breakage of the light emitting device 140 or the solder bumps 142, or the like.

To reduce or prevent the above-mentioned defects in addition to increasing reliability of the light emitting device package 100, a support part 150 may be disposed below the first and second lead frames 120 and 130 in the embodiment. The concept that the support part 150 is disposed below the first and second lead frames 120 and 130 may be understood as a meaning that the support part 150 is disposed in a position opposite to a surface on which the light emitting device 140 is mounted. The support part 150 may be formed of a material having a higher level of strength than that of the package body 110. By way of example, the support part 150 may be formed of a material such as a metal, for example, copper, iron, aluminum or an alloy thereof, or ceramics or the like. The support part 150 may be attached to lower portions of the first and second lead frames 120 and 130 by an adhesive part 155. In particular, when the support part 150 is formed of a metallic material, the adhesive part 155 may be formed of an electrical insulating material, for example, a material such as epoxy resin or the like, in order to electrically isolate the first and second lead frames 120 and 130 from the support part 150.

In an embodiment, the support part 150 may be formed of a material having the coefficient of thermal expansion substantially equal to or lower than that of a material forming the first and second lead frames 120 and 130. By using the material of the support part 150 as described above, damage that may be applied to the light emitting device package 100 due to thermal stress caused by heat generated in the light emitting device 140, the first and second lead frames 120 and 130 and the like may be significantly reduced or eliminated.

At least a portion of the support part 150 may overlap with at least a portion of the separation space 125 formed between the first and second lead frames 120 and 130. That is, the support part 150 may cover at least a portion of the separation space 125. A shape of the support part 150 may be variously modified, and the support part 150 may have multiple regions isolated from each other.

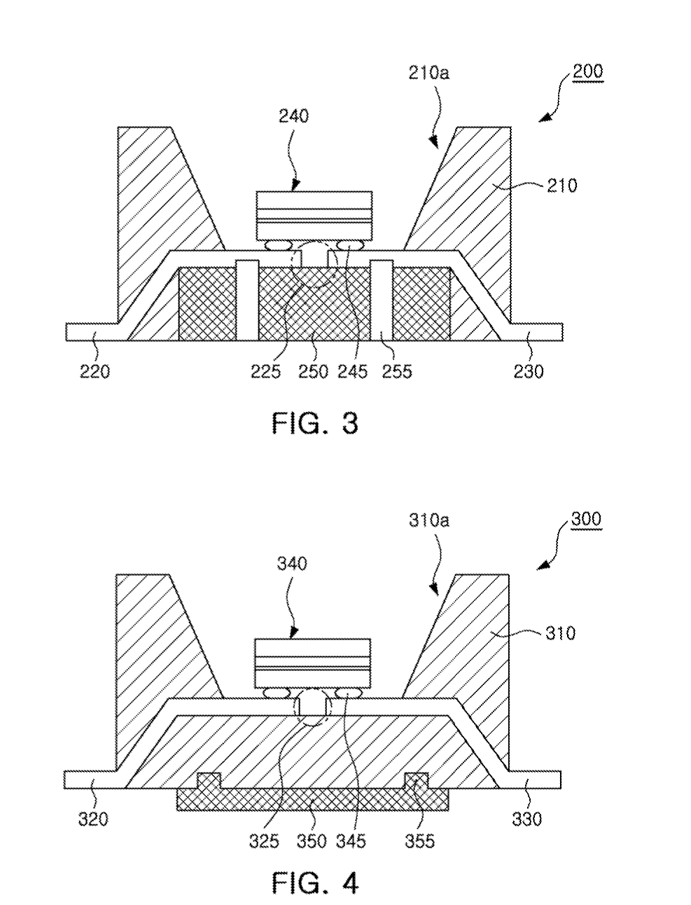

FIG. 3 through FIG. 5 are cross-sectional views of light emitting device packages according to various embodiments.

Referring to FIG. 3, a light emitting device package 200 according to another embodiment may include a package body 210, first and second lead frames 220 and 230 disposed in the package body 210, a light emitting device 240 mounted on the first and second lead frames 220 and 230, and the like. The light emitting device 240 may be configured to emit light in response to an electrical signal applied through the first and second lead frames 220 and 230, and may be disposed in a mounting space 210a of the package body 210.

Portions of the first and second lead frames 220 and 230 may be exposed in the mounting space 210a of the package body 210, and the light emitting device 240 may be mounted on the portions of the first and second lead frames 220 and 230 exposed in the mounting space 210a. The light emitting device 240 may be flip-chip bonded to the first and second lead frames 220 and 230 through solder bumps 245, or may be electrically connected to the first and second lead frames 220 and 230 by a wire or the like.

A support part 250 may be provided below the first and second lead frames 220 and 230. To reduce or prevent thermal stress caused by heat generated during a light emission operation of the light emitting device 240 or external force applied to the light emitting device package 200 from being concentrated on a separation space 225, the support part 250 may have a region at least partially overlapped with the separation space 225. The support part 150 may be formed of a material having a higher level of strength than that of the package body 210, for example, a ceramic material or the like, in order to withstand external force or thermal stress. In addition, in order to reduce or eliminate damage to the light emitting device 200 due to thermal stress caused by heat, the support part 250 may be formed of a material having the coefficient of thermal expansion lower than that of the first and second lead frames 220 and 230.

Referring to FIG. 3, the support part 250 may be fastened to lower portions of the first and second lead frames 220 and 230 through a fastener 255 such as a screw, rivet, hook, or the like. Since the first and second lead frames 220 and 230 may be electrically isolated from each other, the support 250 may be formed of an electrical insulating material such as ceramics or the like. When the support part 250 is formed of an electrical insulating material such as ceramics or the like, the fastener 255 may be a screw formed of a metal or other conductive material.

Alternatively, an insulating layer capable of cutting off electricity may be attached to an upper surface of the support part 250 adhered to the lower surfaces of the first and second lead frames 220 and 230, whereby the support part 250 formed of a metal may be employed in the light emitting device package 200. In this case, in order to prevent electrical connection between the first and second lead frames 220 and 230, the fastener 255 may be formed of an insulating material.

Referring to FIG. 4, a light emitting device package 300 according to another embodiment may include a package body 310 including a mounting space 310a, first and second lead frames 320 and 330, a light emitting device 340 disposed in the mounting space 310a and electrically connected to the first and second lead frames 320 and 330, and the like. As illustrated in FIG. 4, the light emitting device 340 may be mounted on the first and second lead frames 320 and 330 in a flip-chip scheme by solder bumps 345, or may be electrically connected to the first and second lead frames 320 and 330 by a wire or the like.

Referring to FIG. 4, a support part 350 may be provided to protect the light emitting device package 300 from external force being applied to the light emitting device package 300 or thermal stress caused by heat generated in the light emitting device package 300. The support part 350 may be formed of a material having a relatively high level of strength such as a metal alloy, ceramics or the like. As illustrated in FIG. 4, according to another embodiment, the support part 350 may have protrusions 355 inserted into and coupled to grooves disposed on a lower surface of the light emitting device package 300. That is, the support part 350 may be mounted on the lower surface of the light emitting device package 300.

Since the support part 350 may not be directly, physically attached to the first and second lead frames 320 and 330, the support part 350 may be formed of various materials regardless of whether or not the material has electrical conductivity. In addition, in the embodiment illustrated in FIG. 4, in order to reduce or prevent damage such as a phenomenon in which the support part 350 and the package body 310 are separated from each other, or the like, due to thermal stress caused by heat, the support part 350 may be formed of a material having the coefficient of thermal expansion similar to that of the package body 310.

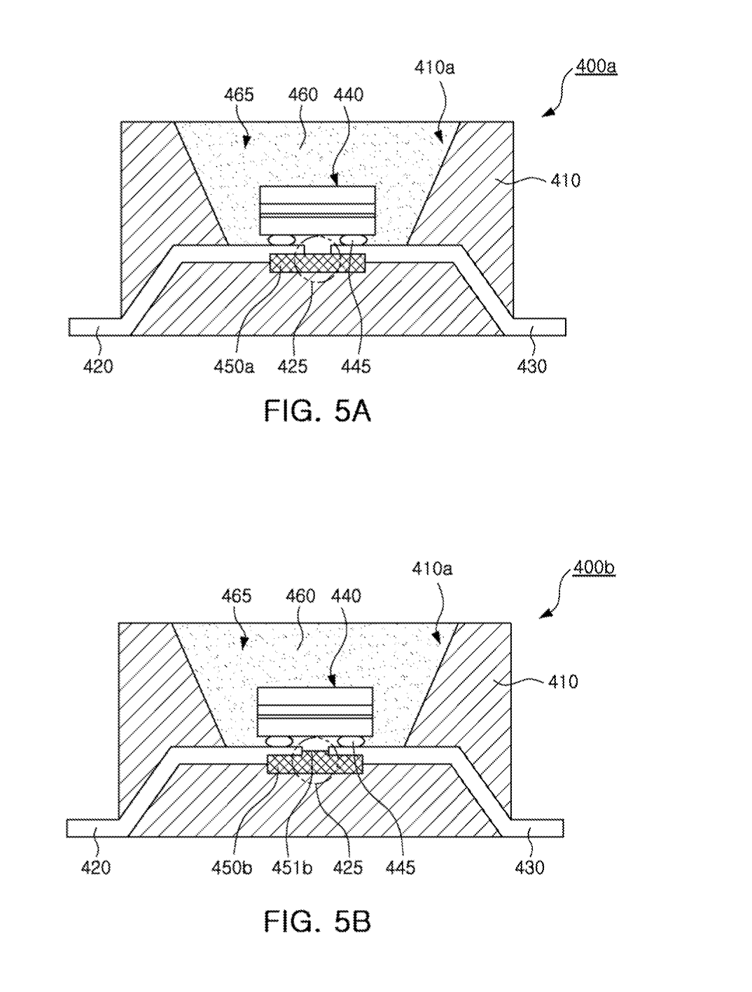

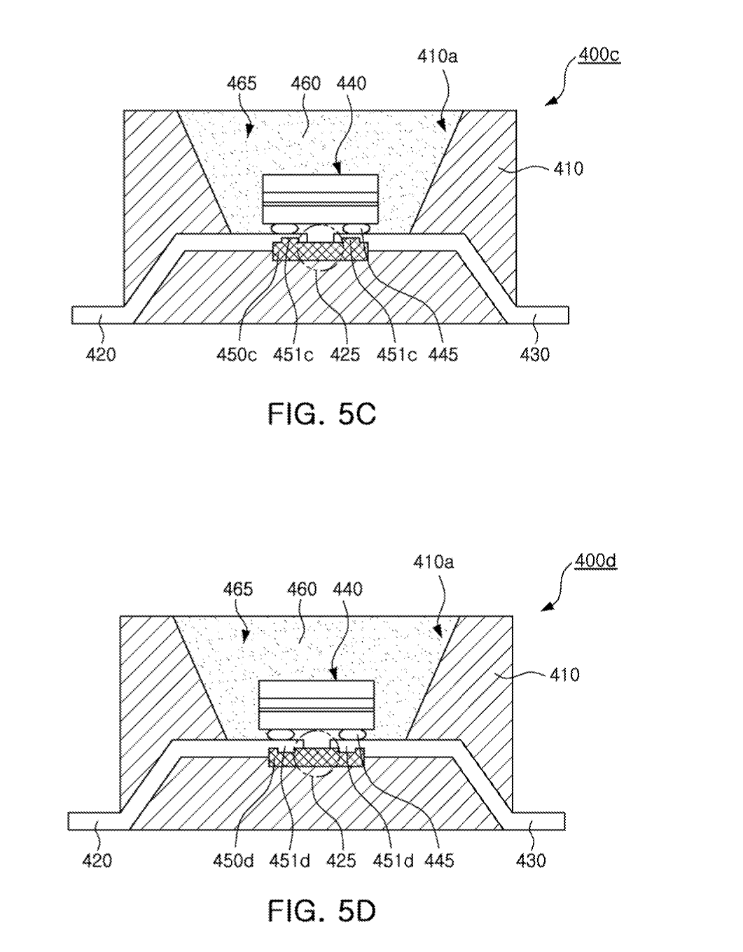

Referring to FIG. 5A, a light emitting device package 400a according to another embodiment may include a package body 410, first and second lead frames 420 and 430, a light emitting device 440, and the like. The light emitting device 440 may be disposed within a mounting space 410a of the package body 410 and may be electrically connected to the first and second lead frames 420 and 430 through solder bumps 445. An encapsulant 460 may be injected into the mounting space 410a to cover the light emitting device 440.

The encapsulant 460 may protect the light emitting device 440 from external impacts and the like and may include a wavelength conversion material 465 to convert a wavelength of light emitted by the light emitting device 440 into another wavelength of light. By way of example, in the case that the light emitting device 440 emits blue light and the wavelength conversion material 465 converts the said blue light into yellow light, the light emitting device package 400a emitting white light may be provided. The encapsulant 460 and the wavelength conversion material 465 may also be applied to the light emitting device packages 100, 200, and 300 according to the embodiments illustrated in FIG. 1 through FIG. 4, in addition to the light emitting device package 400a according to the embodiment illustrated in FIG. 5A.

In the embodiment illustrated in FIG. 5A, the light emitting device package 400a may include a support part 450a for reducing or preventing damage due to thermal stress occurring in an exterior or interior portion of the light emitting device package 400a. Referring to FIG. 5A, the support part 450a may be disposed in a receiving space provided by at least partially removing first and second lead frames 420 and 430. The receiving space may be formed by removing portions of the first and second lead frames 420 and 430 adjacent to a separation space 425.

The support part 450a may be attached to the first and second lead frames 420 and 430 within the receiving space, by adhesive tape or the like. In a particular embodiment, the support part 450a may be attached to the first and second lead frames 420 and 430 by resin tape having adhesive and insulating properties. In this case, since the support part 450a is electrically isolated from the first and second lead frames 420 by the resin tape, the support part 450a may be formed of a conductive metal alloy or the like, in addition to a ceramic material having insulating properties.

In another embodiment, the support part 450a may be fastened to the first and second lead frames 420 and 430 while being fitted to and inserted into the receiving space. That is, the support part 450a may have substantially the same surface area as the receiving space, and may be inserted into the receiving space without the use of a separate adhesive member having adhesion properties. In this case, in order to keep the first and second lead frames 420 and 430 from being electrically connected to each other, the support part 450a may be formed of an insulating material.

Since the support part 450a is inserted into the space provided in the first and second lead frames 420 and 430, the light emitting device package 400a may be broken due to a difference in coefficients of thermal expansion between the support part 450a and the first and second lead frames 420 and 430 in the case that heat is generated by a light emission operation of the light emitting device 440. In order to prevent such defects, the support part 450a may be formed of a material having the coefficient of thermal expansion similar to that of the first and second lead frames 420 and 430 or a material having the coefficient of thermal expansion lower than that of the first and second lead frames 420 and 430.

Referring to FIG. 5B, in this embodiment, the light emitting device package 400b may be similar to the light emitting device package 400a described above. However, the support part 450b may include a protrusion 451b extending into at least a part of the separation space 425.

Referring to FIG. 5C, in this embodiment, the light emitting device package 400c may be similar to the light emitting device package 400a described above. However, the support part 450c includes protrusions 451c extending into corresponding openings of the first and second lead frames 420 and 430. In a particular example, the protrusions 451c may include ridges extending substantially parallel with the separation space 425.

Referring to FIG. 5D, in this embodiment, the light emitting device package 400c may be similar to the light emitting device package 400a described above. However, the support part 450d includes openings 451d configured to receive corresponding protrusions of the first and second lead frames 420 and 430. In a particular example, the openings 451d may include grooves extending substantially parallel with the separation space 425.

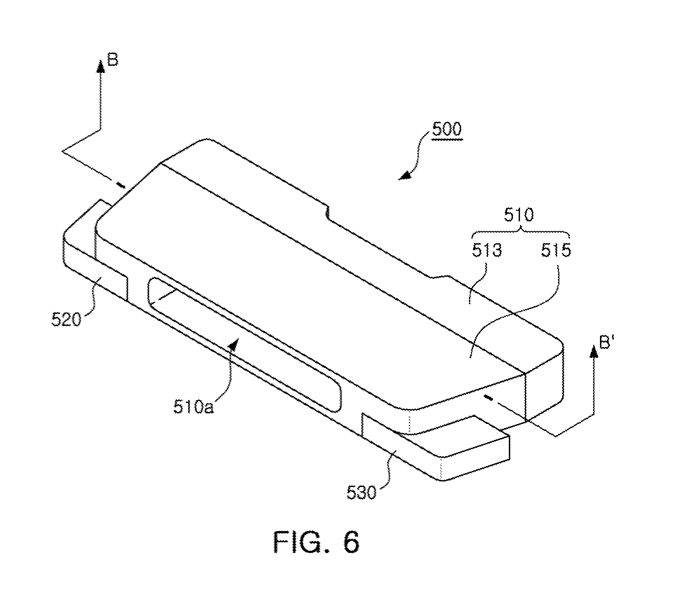

FIG. 6 is a perspective view illustrating a light emitting device package according to another embodiment.

Referring to FIG. 6, a light emitting device package 500 according to another embodiment may be a side view type light emitting device package. In the embodiment illustrated in FIG. 6, the light emitting device package 500 may include a package body 510, first and second lead frames 520 and 530 and the like. The package body 510 may provide a mounting space 510a and a light emitting device may be disposed within the mounting space 510a.

The package body 510 may include a first body 513 and a second body 515. The first and second lead frames 520 and 530 may be provided between the first body 513 and the second body 515 or may be provided within the first body 513. At least portions of the first and second lead frames 520 and 530 may be outwardly exposed. Although the embodiment illustrated in FIG. 6 illustrates a case in which portions of the first and second lead frames 520 and 530 are exposed outwardly from the second body 515, the portions of the first and second lead frames 520 and 530 may be exposed outwardly from the first body 513.

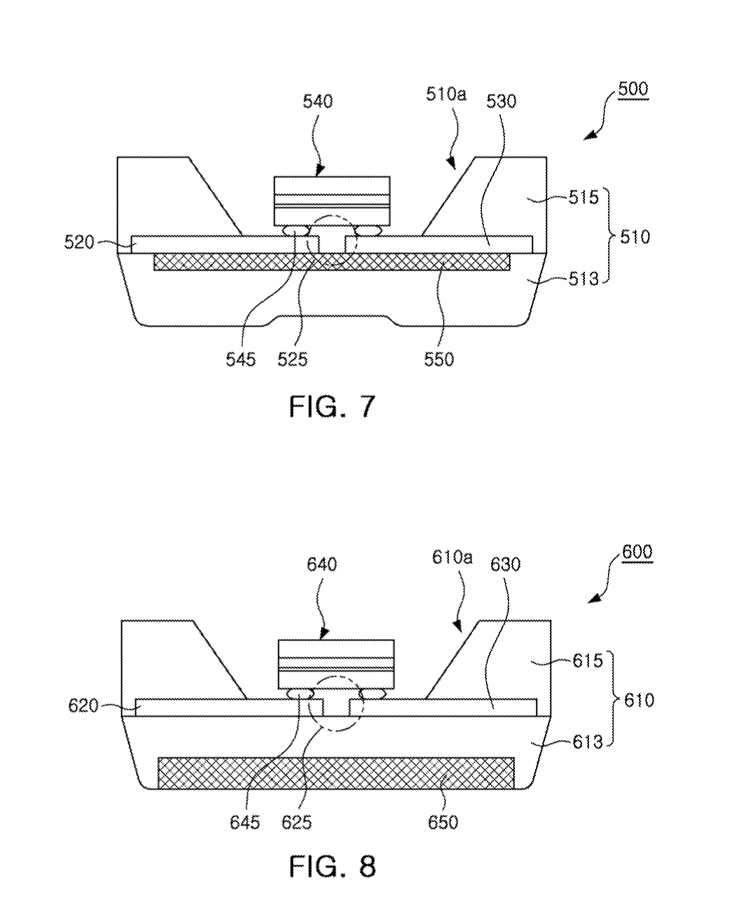

FIG. 7 is a cross-sectional view illustrating a cross-section of the light emitting device package illustrated in FIG. 6, taken along line B-B′.

Referring to FIG. 7, a light emitting device 540 may be disposed within the mounting space 510a of the package body 510. The light emitting device 540 may be mounted on the first and second lead frames 520 and 530 within the mounting space 510a, through solder bumps 545 or the like. In order to increase luminance of the light emitting device package 500, a reflective layer formed of a material having a high degree of reflectance may be provided on an interior surface of the second body 515 adjacent to the light emitting device 540.

A separation space 525 may be provided between the first and second lead frames 520 and 530 in order to electrically isolate the first and second lead frames 520 and 530 from each other. When external force is applied to the light emitting device package 500 or thermal stress due to heat generated by a light emission operation is applied to the light emitting device package 500, the external force or thermal stress may be concentrated on the separation space 525, such that the light emitting device package 500 may be broken.

In the embodiment illustrated in FIG. 7, in order to decrease the external force or thermal stress applied to the separation space 525, a support part 550 may be disposed within the package body 510. Referring to FIG. 7, the support part 550 may be disposed within the first body 513 and in particular, may be disposed to be adjacent to a boundary surface between the first body 513 and the second body 515. The support part 550 may be formed to cover at least a portion of the separation space 525 between the first and second lead frames 520 and 530. According to various embodiments, the support part 550 may be attached to lower surfaces of the first and second lead frames 520 and 530 or may be spaced apart from the lower surfaces of the first and second lead frames 520 and 530 by a predetermined distance.

In the case that the support part 550 is attached to the lower surfaces of the first and second lead frames 520 and 530, adhesive tape and the like, formed of an insulating resin or the like, may be selectively provided between the first and second lead frames 520 and 530 and the support part 550. Thus, the support part 550 may be further stably adhered to the first and second lead frames 520 and 530. In addition, since the first and second lead frames 520 and 530 and the support part 550 are electrically isolated from each other by the adhesive tape, the support part 550 may also be formed of a conductive material such as a metal alloy or the like, in addition to an insulating material such as ceramics or the like.

FIG. 8 is a cross-sectional view illustrating a light emitting device package according to another embodiment.

Referring to FIG. 8, a light emitting device package 600 configured to laterally emit light as illustrated in FIGS. 6 and 7 is illustrated. The light emitting device package 600 according to the embodiment of FIG. 8 may include a package body 610 providing amounting space 610a, a light emitting device 640 mounted on first and second lead frames 620 and 630 in the mounting space 610a, and the like. The light emitting device 640 may be mounted on the first and second lead frames 620 and 630 through solder bumps 645 or the like.

The package body 610 may include a first body 613 and a second body 615. A support part 650 may be included in the first body 613. The support part 650 may overlap with at least a portion of an separation space 625 formed between the first and second lead frames to thereby reduce or prevent externally applied force or thermal stress caused by heat from being concentrated on the separation space 625. That is, the support part 650 may reduce or prevent damage to the light emitting device package 600 due to various factors.

In the embodiment illustrated in FIG. 8, the support part 650 may be provided within the first body 613 to be adjacent to a lower surface of the first body 613. In an embodiment, the first body 613 having the support part 650 may be formed using an injection process of the first body 613 in such a manner that the first body 613 includes the support part 650 previously formed of a material such as a metal alloy, ceramics or the like. In another embodiment, at the time of manufacturing the first body 613, after forming a groove for accommodating the support part 650 in the lower surface of the first body 613, the support part 650 may be received in the groove, whereby the package body 610 as illustrated in FIG. 8 may be manufactured.

The support part 650 may be disposed in the groove in a lower portion of the first body 613 while being inserted thereinto or may be attached to an interior portion of the groove by a separate adhesive resin, adhesive tape or the like. Since the support part 650 is disposed to be spaced apart from the first and second lead frames 620 and 630, a material of the support part 650 may be freely selected regardless of properties such as electrical conductivity and insulating properties. In an embodiment, in order to significantly reduce impacts due to thermal stress caused by heat, the support part 650 may be formed of a material having the coefficinent of thermal expansion slightly different from that of the first body 613.

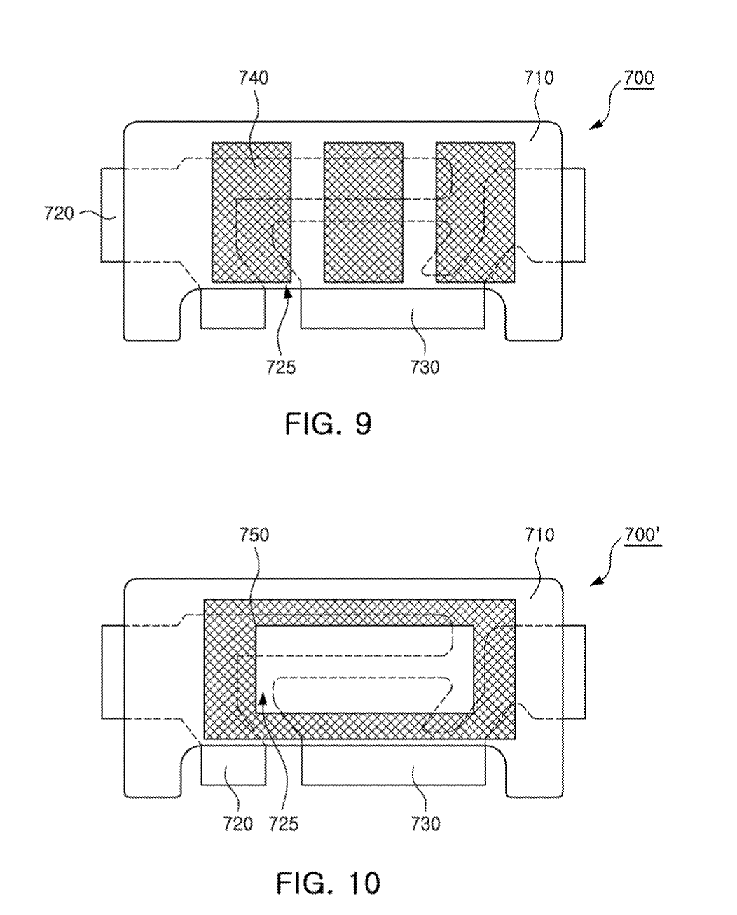

FIG. 9 through FIG. 11 are plan views respectively illustrating a light emitting device package according to various embodiments. FIG. 9 through FIG. 11 are plan views respectively illustrating one surface of a light emitting device package. By way of example, FIG. 9 through FIG. 11 are plan views respectively illustrating a light emitting device package, viewed in a direction opposite to a direction in which the light emitting device package mainly emits light.

Referring to FIG. 9 first, a light emitting device package 700 according to the embodiment illustrated in FIG. 9 may include a package body 710, a pair of lead frames 720 and 730, and a support part 740. Portions of the pair of lead frames 720 and 730 may protrude outwardly from the package body 710 in a plane direction illustrated in FIG. 9. The portions of the pair of lead frames 720 and 730 protruding outwardly from the package body 710 may be connected to an external circuit substrate and may be configured to receive an electrical signal input.

The support part 740 may have multiple regions separated from each other. Although embodiment illustrated in FIG. 9 illustrates a case in which the support part 740 has three regions separated from each other, a greater or lesser amount of regions may be included in the support part 740. In addition, although the embodiment illustrated in FIG. 9 illustrates a case in which the support part 740 has a rectangular shape, it is merely provided byway of example. Shapes and areas of respective regions included in the support part 740 may be variously modified.

The support part 740 may disperse external force applied to the light emitting device package 700, in particular, external force applied to an separation space 725 between the pair of lead frames 720 and 730, or stress and the like generated due to heat, to thereby reduce or prevent breakage of the light emitting device package 700. In order to more efficiently disperse external force or stress and the like applied to the separation space 725, at least one of the regions included in the support part 740 may overlap with at least a portion of the separation space 725.

Referring to FIG. 10, a light emitting device package 700′ according to the embodiment illustrated in FIG. 10 may include a support part 750 having a shape different from that of the light emitting device package 700 according to the exemplary embodiment of FIG. 9. In the embodiment illustrated in FIG. 10, the support part 750 may have an opening provided in a central portion thereof. Similarly to the embodiment of FIG. 9, at least a portion of the support part 750 may cover at least a portion of the separation space 725 formed between the pair of lead frames 720 and 730.

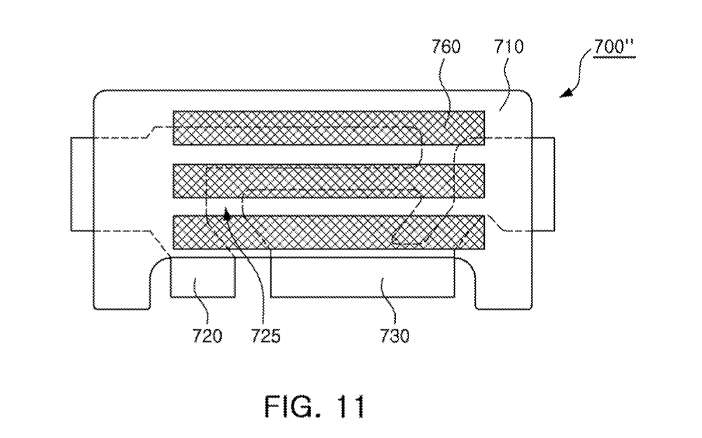

Referring to FIG. 11, a light emitting device package 700″ according to the embodiment illustrated in FIG. 11 may include a support part 760 having an elongated shape extended in a horizontal direction of FIG. 11. The support part 760 may have multiple regions respectively having rectangular shapes elongated and extended in the horizontal direction of FIG. 11, and the number or shapes of the regions included in the support part 760 may be variously modified. Similarly to the embodiments of FIGS. 9 and 10, at least a portion of the support part 760 may overlap with a portion of the separation space 725, in the embodiment of FIG. 11.

In the embodiments of FIGS. 9 through 11, the support parts 740, 750 and 760 may be disposed within the package body 710 or may be attached to an outer surface of the package body 710. In the case that the support parts 740, 750 and 760 are disposed within the package body 710, the support parts 740, 750 and 760 may be attached to the pair of the lead frames 720 and 730 within the package body 710 by a fastening member such as adhesive tape, a screw or the like, as described with reference to FIG. 2, FIG. 3, FIG. 7, and the like. If the support parts 740, 750 and 760 are attached to an outer surface of the package body 710, the support parts 740, 750 and 760 may be mounted in grooves or the like, provided in a lower portion of the package body 710, as described with reference to FIG. 4, FIG. 8, and the like.

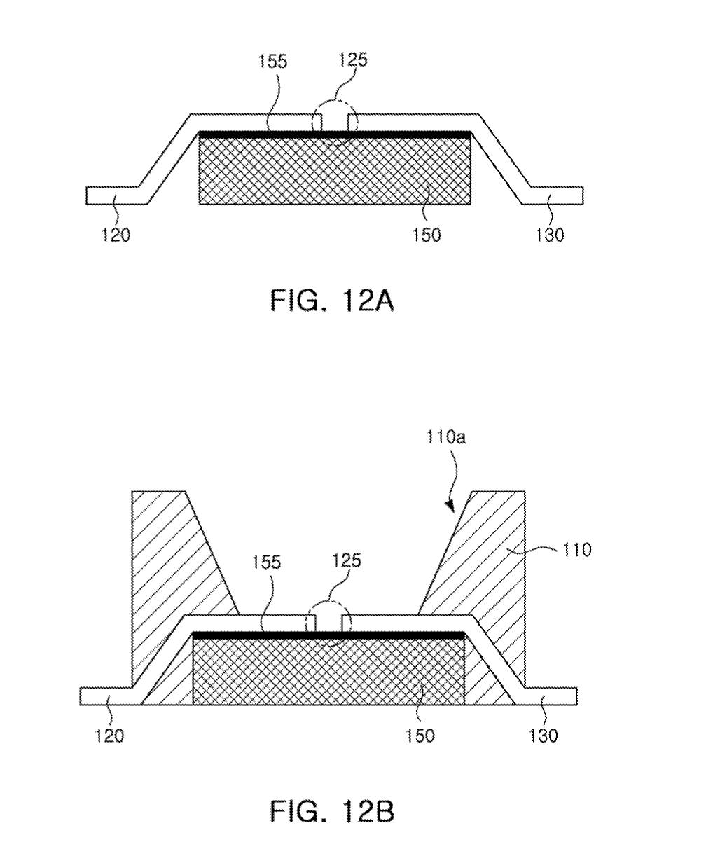

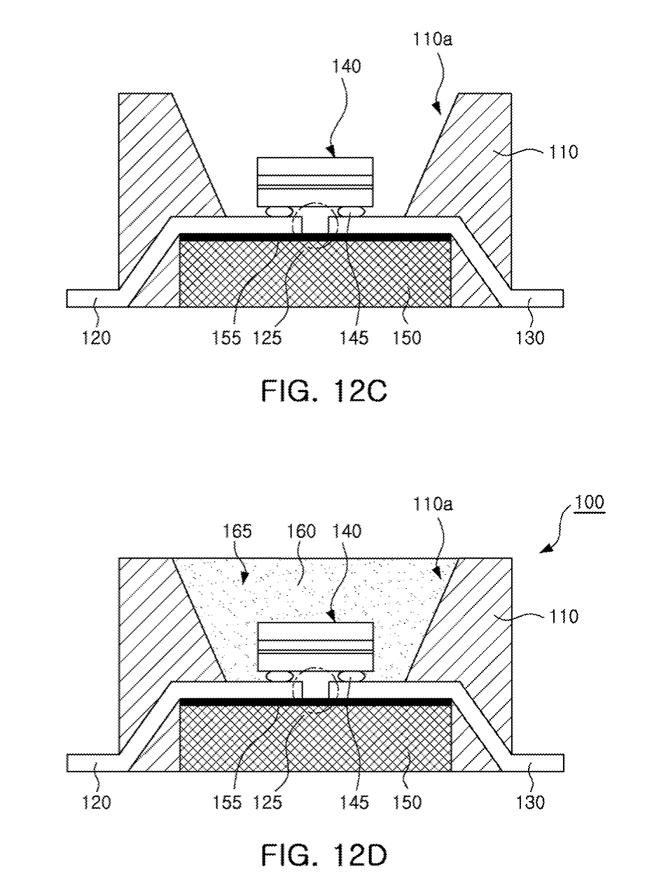

FIG. 12a through FIG. 12d are views illustrating a method of manufacturing the light emitting device package according to an embodiment. By the manufacturing method illustrated in FIG. 12a through FIG. 12d, the light emitting device package 100 according to the embodiments of FIGS. 1 and 2 may be manufactured.

Referring to FIG. 12a first, a pair of the first and second lead frames 120 and 130 may be prepared to manufacture a light emitting device package. The first and second lead frames 120 and 130 may be isolated from each other, and the separation space 125 may be formed between the first and second lead frames 120 and 130.

The support part 150 may be attached to the lower surfaces of the first and second lead frames 120 and 130. The support part 150 may be formed of a material such as a metal alloy, ceramics or the like and may be attached to the lower surfaces of the first and second lead frames 120 and 130 by the adhesive part 155. If the support part 150 is formed of a metal alloy, the adhesive part 155 may include resin tape having insulating properties, and the like.

Referring to FIG. 12b, the package body 110 may be formed to include the support part 150 and the first and second lead frames 120 and 130 therein, using an injection molding process. The package body 110 may be formed to have the mounting space 110a, and at least a portion of the first and second lead frames 120 and 130 may be exposed in the mounting space 110a.

Referring to FIG. 12c, the light emitting device 140 may be disposed in the mounting space 110a. In the embodiment of FIG. 12c, a case in which the light emitting device 140 is flip-chip bonded to the first and second lead frames 120 and 130 by the solder bumps 145 is illustrated, but it is merely provided by way of example. In another embodiment, the light emitting device 140 may be electrically connected to the first and second lead frames 120 and 130 by wire bonding or the like.

If the light emitting device 140 is flip-chip bonded to the first and second lead frames 120 and 130, at least a portion of the separation space 125 may be positioned below the light emitting device 140. When external force is applied to the light emitting device package 100 or thermal stress occurs within the light emitting device package 100 due to heat generated by a light emission operation or the like, the external force or thermal stress may be concentrated on the separation space 125. Thus, the light emitting device package 100 may be damaged from the separation space 125 due to the external force and thermal stress, or the solder bumps 145 may be damaged, such that the light emitting device 140 may be separated from the first and second lead frames 120 and 130.

In this embodiment, the support part 150 may be disposed to overlap with at least a portion of the separation space 125, such that the external force and thermal stress may be dispersed to thereby prevent breakage of the light emitting device package 100. Meanwhile, in order to efficiently protect the light emitting device package 100 from thermal stress due to heat, the support part 150 may have the coefficient of thermal expansion similar to or lower than that of the first and second lead frames 120 and 130.

Referring to FIG. 12d, the encapsulant 160 may be injected into the mounting space 110a. The encapsulant 160 may be formed of a light-transmissive resin having a higher light transmissivity and may contain silicon or epoxy resin. The encapsulant 160 may include the wavelength conversion material 165 configured to converting a wavelength of light emitted by the light emitting device 140 into another wavelength of light. Since the encapsulant 160 may include the wavelength conversion material 165, a color of light emitted by the light emitting device package 100 may be different from that of light emitted by the light emitting device 140, and the light emitting device 140 may be protected thereby.

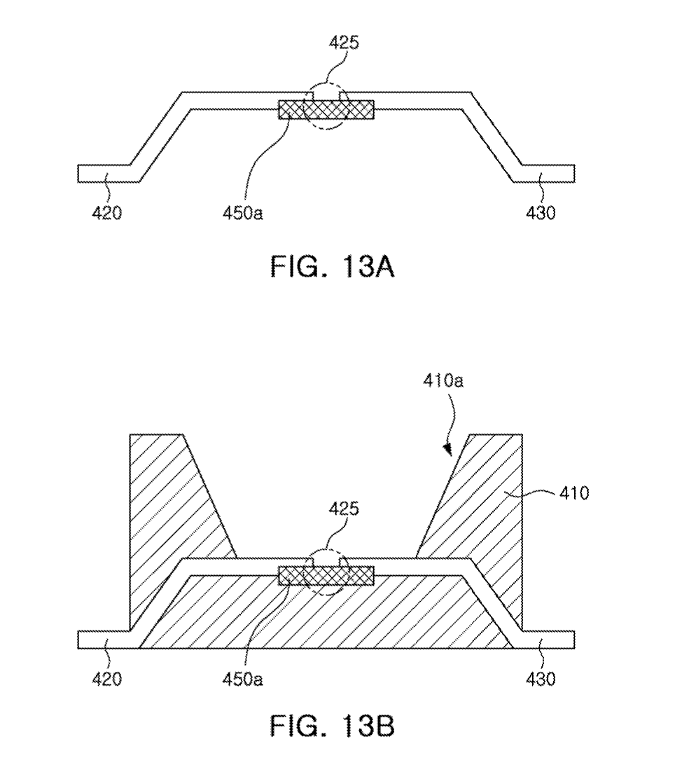

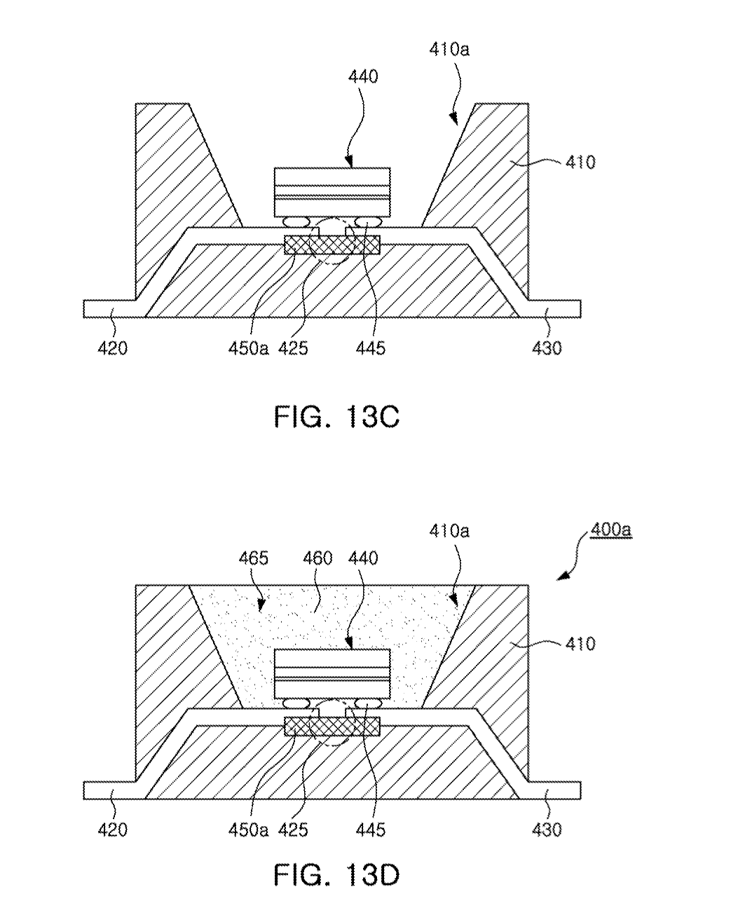

FIG. 13a through FIG. 13d are views illustrating a method of manufacturing the light emitting device package according to another embodiment. With reference to the manufacturing method illustrated in FIG. 13a through FIG. 13d, the light emitting device package 400a according to the embodiment of FIGS. 5A-D may be manufactured. Although a method of manufacturing an embodiment according to FIG. 5A is used as an example the method may be modified according to the other structures of FIGS. 5B-D.

Referring to FIG. 13a, the support part 450a together with the first and second lead frames 420 and 430 may be prepared. The first and second lead frames 420 and 430 may be spaced apart from each other and the separation space 425 may be formed therebetween. The support part 450a may be formed to cover at least a portion of the separation space 425.

In the embodiment illustrated in FIG. 13a, portions of the first and second lead frames 420 and 430 adjacent to the separation space 425 may be removed to prepare a receiving space for receiving the support part 450aa therein. The support part 450a may be fastened to the first and second lead frames 420 and 430 while being fitted to and inserted into the receiving space, or may be fastened to the first and second lead frames 420 and 430 within the receiving space by a separate adhesive part. In the case that the adhesive part is separately provided, the support part 450a may be formed of various materials, regardless of whether or not the material has electrical conductivity and insulating properties. In the case that a separate adhesive part is not provided, the support part 450a may be formed of a ceramic material or the like, having insulating properties and a higher degree of strength.

Referring to FIG. 13b, the package body 410 may be formed. The package body 410 may include the mounting space 410a and at least a portion of the first and second lead frames 420 and 430 may be exposed in the mounting space 410a. Referring to FIGS. 13c and 13d, the light emitting device 440 may be disposed within the mounting space 410a and may be electrically connected to the first and second lead frames 420 and 430 by the solder bumps 445 or the like. In the mounting space 410a, the encapsulant 460 including the wavelength conversion material 465 may be injected to protect the light emitting device 440.

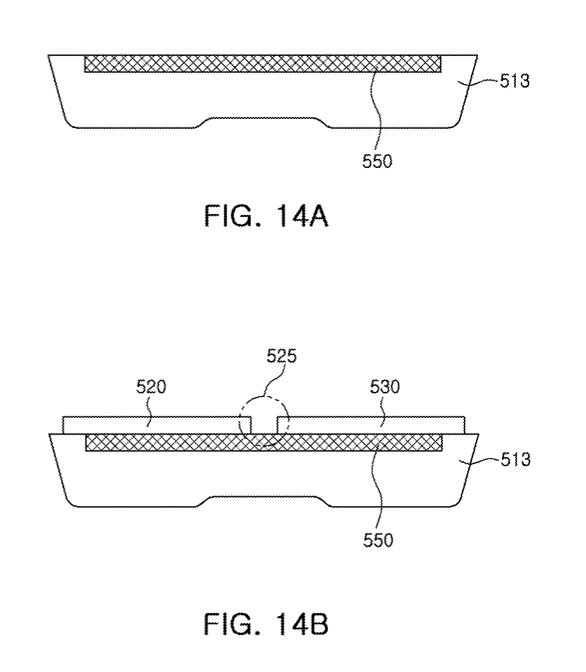

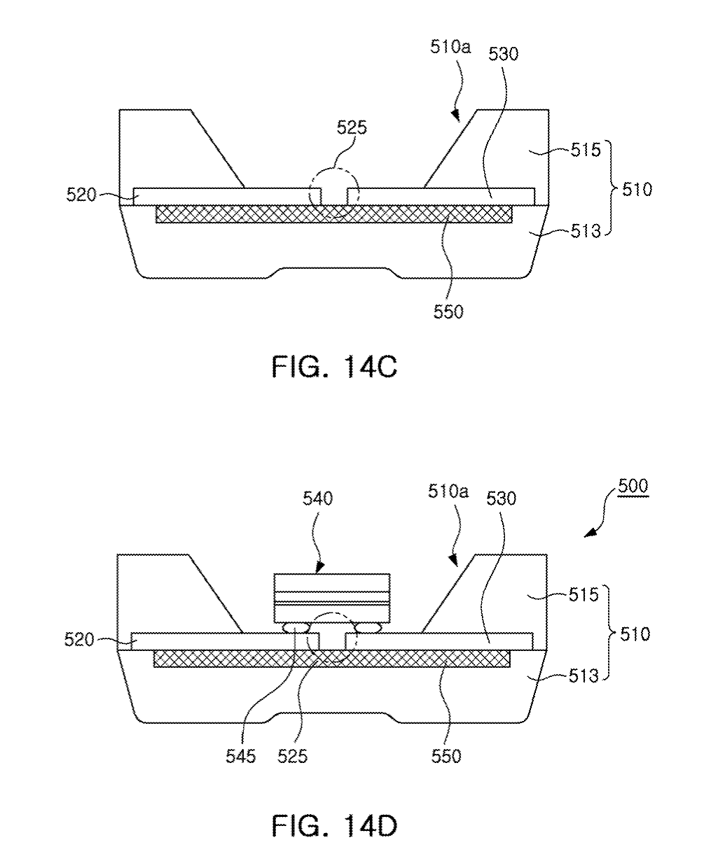

FIG. 14a through FIG. 14d are views illustrating a method of manufacturing a light emitting device package according to another embodiment. By the manufacturing method illustrated in FIG. 14a through FIG. 14d, the light emitting device package 500 according to the embodiment of FIGS. 6 and 7 may be manufactured.

Referring to FIG. 14a, the first body portion 513 including the support part 550 may be provided. The support part 550 may contain a metal alloy, ceramics or the like. Then, referring to FIG. 14b, a pair of the first and second lead frames 520 and 530 may be disposed on the support part 550 and the first body portion 513. The first and second lead frames 520 and 530 may be attached to the support part 550 by resin tape or the like, having adhesion and insulation properties.

In particular, if the support part 550 contains a metal alloy, the first and second lead frames 520 and 530 may be attached to an upper surface of the support part 550 by resin tape having insulating properties so as to electrically isolate the first and second lead frames 520 and 530 from each other. The separation space 525 may be provided between the first and second lead frames 520 and 530, and at least a portion of the separation space 525 may overlap with the support part 550.

Referring to FIG. 14c, the second body portion 515 may be provided on the first and second lead frames 520 and 530 and the first body portion 513. The second body portion 515 may include the mounting space 510a for mounting the light emitting device therein. The interior surface of the second body portion 515 adjacent to the mounting space 510a may be coated with a material having a higher degree of reflectance and may include a reflective wall. Finally, as illustrated in FIG. 14d, the light emitting device 540 may be disposed in the mounting space 510a and may be mounted on the first and second lead frames 520 and 530 by the solder bumps 545 or the like, whereby the light emitting device package 500 may be manufactured.

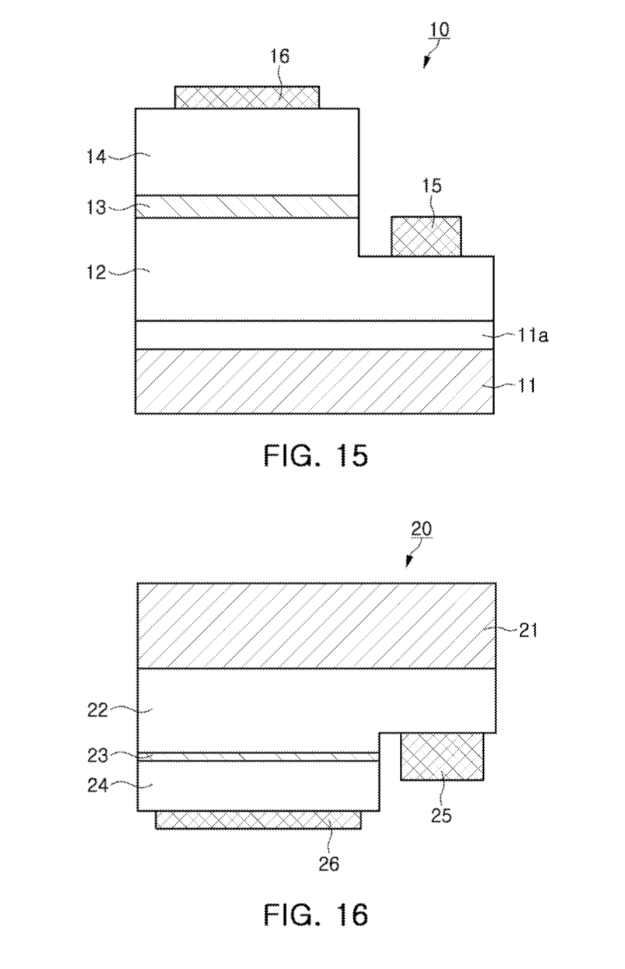

FIG. 15 through FIG. 20 are views illustrating light emitting devices applicable to the light emitting device package according to various embodiments.

Referring to FIG. 15 first, a light emitting device 10 according to an embodiment may include a substrate 11, a first conductivity-type semiconductor layer 12, an active layer 13, and a second conductivity-type semiconductor layer 14. In addition, a first electrode 15 may be formed on the first conductivity-type semiconductor layer 12 and a second electrode 16 may be formed on the second conductivity-type semiconductor layer 14. An ohmic-contact layer may be further selectively provided between the second electrode 16 and the second conductivity-type semiconductor layer 14.

According to various embodiments, the substrate 11 may be at least one selected from an insulating substrate, a conductive substrate or a semiconductor substrate. The substrate 11 may be, for example, sapphire, SiC, Si, MgAl₂O₄, MgO, LiAlO₂, LiGaO₂, or GaN. A homogeneous substrate, a GaN substrate may be selected as the substrate 11 for epitaxial growth of a GaN material, and a heterogeneous substrate may be mainly, sapphire, silicon carbide (SiC) or the like. In the case of using the heterogeneous substrate, defects such as dislocations and the like may be caused due to a difference in lattice constants between a substrate material and a film material. In addition, warpage may occur at the time of a temperature variation due to a difference in coefficients of thermal expansion between the substrate material and the film material, and such a warpage phenomenon may cause cracks in the film. In order to solve such defects, a buffer layer 11a may be disposed between the substrate 11 and the first conductivity-type semiconductor layer 12 provided as a GaN based layer.

In the case of growing the first conductivity-type semiconductor layer 12 containing GaN on the heterogeneous substrate, dislocation density may be increased due to mismatch in lattice constants between the substrate material and the film material, and cracks and warpage may occur due to the difference in coefficients of thermal expansion. In order to reduce a chance of or prevent the dislocation and cracks as described above, the buffer layer 11a may be disposed between the substrate 11 and the first conductivity-type semiconductor layer 12. The buffer layer 11a may adjust a degree of warpage of the substrate when an active layer is grown, to reduce a wavelength dispersion of a wafer.

The buffer layer 11a may be made of AlₓIn_{y}Ga_{1-x-y}N (0≦x≦1, 0≦y≦1), in particular, GaN, AlN, AlGaN, InGaN, or InGaN/AlN, and a material such as ZrB₂, HfB₂, ZrN, HfN, TiN, or the like, may also be used. Also, the buffer layer may be formed by combining multiple layers or by gradually changing a composition.

A silicon (Si) substrate has a coefficient of thermal expansion significantly different from that of GaN. Thus, in case of growing a GaN-based film on the silicon substrate, when a GaN film is grown at a high temperature and is subsequently cooled to room temperature, tensile stress is applied to the GaN film due to the difference in the coefficients of thermal expansion between the silicon substrate and the GaN film, causing cracks. In this case, in order to reduce a chance of or prevent the occurrence of cracks, a method of growing the GaN film such that compressive stress is applied to the GaN film while the GaN film is being grown is used to compensate for tensile stress. A significant difference in lattice constants between silicon (Si) and GaN involves a higher possibility of the occurrence of defects. In the case of using a silicon substrate, the buffer layer 11a having a composite structure may be used in order to control stress for restraining warpage as well as controlling a defect.

First, an AlN layer may be formed on the substrate 11 in order to form the buffer layer 11a. In this case, a material not including gallium (Ga) may be used in order to prevent a reaction between silicon (Si) and gallium (Ga). Besides AlN, a material such as SiC, or the like, may also be used. The AlN layer may be grown at a temperature ranging from about 400° C. to about 1300° C. by using an aluminum (Al) source and a nitrogen (N) source. An AlGaN interlayer may be inserted between multiple AlN layers in order to control stress.

The first conductivity-type semiconductor layer 12 and the second conductivity-type semiconductor layer 14 may be an n-type impurity doped semiconductor layer and a p-type impurity doped semiconductor layer, respectively but are not limited thereto. The first conductivity-type semiconductor layer 12 and the second conductivity-type semiconductor layer 14 may be a p-type semiconductor layer and an n-type semiconductor layer, respectively. By way of example, the first conductivity-type semiconductor layer 12 and the second conductivity-type semiconductor layer 14 may be formed of a group III nitride semiconductor, for example, a material having a composition of AlₓIn_{y}Ga_{1-x-y}N (0≦x≦1, 0≦y≦1, 0≦x+y≦1). The materials of the first conductivity-type semiconductor layer 12 and the second conductivity-type semiconductor layer 14 are not limited thereto, and may be an AlGaInP based semiconductor or an AlGaAs based semiconductor.

The first and second conductivity-type semiconductor layers 12 and 14 may have a single layer structure but may have a multilayer structure in which respective layers have different compositions, thicknesses or the like. For example, each of the first and second conductivity-type semiconductor layers 12 and 14 may include a carrier injection layer capable of improving injection efficiency of electrons and holes and further, may have a superlattice structure formed in various manners.

The first conductivity-type semiconductor layer 12 may further include a current spreading layer in a portion thereof adjacent to the active layer 13. The current spreading layer may have a structure in which multiple AlₓIn_{y}Ga_{1-x-y}N layers having different compositions or different impurity contents are repeatedly stacked or may be partially formed of an insulating material layer.

The second conductivity-type semiconductor layer 14 may further include an electron blocking layer in a portion thereof adjacent to the active layer 13. The electron blocking layer may have a structure in which multiple AlₓIn_{y}Ga_{1-x-y}N layers having different compositions are stacked or may have at least one layer configured of Al_{y}Ga_{(1-y)}N. The second conductivity-type semiconductor layer 14 may have a band gap greater than that of the active layer 13 to prevent electrons from passing over the second conductivity-type semiconductor layer 14.

In an embodiment, the first and second conductivity-type semiconductor layers 12 and 14 and the active layer 13 may be formed using an MOCVD device. In order to manufacture the first and second conductivity-type semiconductor layers 12 and 14 and the active layer 13, an organic metal compound gas (for example, trimethylgallium (TMG), trimethyl aluminum (TMA) or the like) and a nitrogen-containing gas (ammonia (NH₃) or the like) are supplied as a reaction gas, to a reaction container in which the growth substrate 11 is installed, and a temperature of the substrate is maintained at a high temperature of about 900° C. to about 1100° C., such that gallium nitride compound semiconductors may be grown on the substrate while supplying an impurity gas thereto if necessary, to thereby allow the gallium nitride compound semiconductors to be stacked as an undoped layer, an n-type layer, and a p-type layer, on the substrate. An n-type impurity may be Si, widely known in the art and a p-type impurity may be Zn, Cd, Be, Mg, Ca, Ba or the like. As the p-type impurity, Mg and Zn may be mainly used.

In addition, the active layer 13 interposed between the first and second conductivity-type semiconductor layers 12 and 14 may have a multiple quantum well (MQW) structure in which quantum well layers and quantum barrier layers are alternately stacked. For example, if the active layer 13 includes a nitride semiconductor, the active layer 13 may have a structure of GaN and InGaN. In some embodiments, the active layer 13 may have a single quantum well (SQW) structure. The first or second electrode 15 or 16 may contain a material such as Ag, Ni, Al, Rh, Pd, Ir, Ru, Mg, Zn, Pt, Au or the like. The light emitting device 10 illustrated in FIG. 15 may have an Epi-Up structure and accordingly, may be electrically connected to lead frames by a conductive wire or the like, when the light emitting device 10 is included within the light emitting device package 100, 200, 300, 400, 500, 600 or 700.

Referring to FIG. 16, a light emitting device 20 according to another embodiment may include a support substrate 21, first and second conductivity-type semiconductor layers 22 and 24, an active layer 23, first and second electrodes 25 and 26, and the like. The light emitting device 20 according to the embodiment illustrated in FIG. 16 may be attached to the lead frames of the light emitting device package 100, 200, 300, 400, 500, 600, 700, or the like by flip-chip bonding. Since light generated in the active layer 23 may be emitted upwardly, the support substrate 21 may be formed of a material having light-transmissive properties.

In addition, in order to reflect light generated in the active layer 23 and moving in a downward direction, the second electrode 26 may be formed of a material having electrical conductivity and reflective properties. In an example, the second electrode 26 may be formed of at least one among Ag, Ni, Al, Rh, Pd, Ir, Ru, Mg, Zn, Pt, and Au.

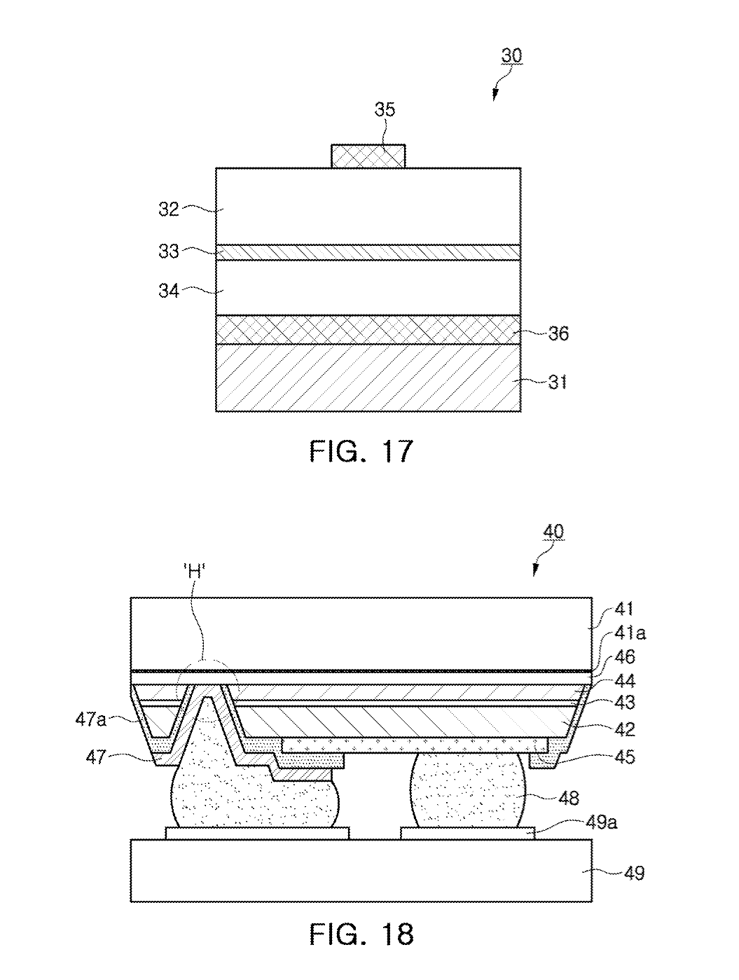

Referring to FIG. 17, a light emitting device 30 according to another embodiment is illustrated. The light emitting device 30 according to the embodiment illustrated in FIG. 17 may include a first conductivity-type semiconductor layer 32, an active layer 33, and a second conductivity-type semiconductor layer 34, a first electrode 35 attached to the first conductivity-type semiconductor layer 32, and a second electrode 36 attached to the second conductivity-type semiconductor layer 34, and the like. A conductive substrate 31 may be disposed on a lower surface of the second electrode 36 and may be directly mounted on the lead frames or the like, included within the light emitting device package 100, 200, 300, 400, 500, 600, 700, or the like. Within the light emitting device package 100, 200, 300, 400, 500, 600, 700, or the like, the conductive substrate 31 may be directly mounted on at least one of a pair of the lead frames, and the first electrode 35 may be electrically connected to the remainder lead frame by a wire or the like.

In a similar manner to the case of the light emitting devices 10 and 20, the first conductivity-type semiconductor layer 32 and the second conductivity-type semiconductor layer 34 may include an n-type nitride semiconductor and a p-type nitride semiconductor, respectively. Meanwhile, the active layer 33 interposed between the first and second conductivity-type semiconductor layers 32 and 34 may have a multiple quantum well (MQW) structure in which nitride semiconductor layers having different compositions are alternately stacked and may selectively have a single quantum well (SQW) structure.

The first electrode 35 may be disposed on an upper surface of the first conductivity-type semiconductor layer 32 and the second electrode 36 may be disposed on a lower surface of the second conductivity-type semiconductor layer 34. Light generated due to the recombination of electrons and holes in the active layer 33 of the light emitting device 30 shown in FIG. 17 may be emitted to an upper surface of the first conductivity-type semiconductor layer 32 on which the first electrode 35 is disposed. Thus, in order to reflect light generated in the active layer 33 in a direction toward the upper surface of the first conductivity-type semiconductor layer 32, the second electrode 36 may be formed of a material having a higher degree of reflectance. The second electrode 36 may contain at least one of Ag, Al, Ni, Cr, Cu, Au, Pd, Pt, Sn, Ti, W, Rh, Ir, Ru, Mg, and Zn or an alloy material containing these materials.

Referring to FIG. 18, a light emitting device 40 according to this embodiment may include a first conductivity-type semiconductor layer 42 and a second conductivity-type semiconductor layer 44, an active layer 43 interposed therebetween, and first and second electrodes 45 and 46 connected to the first and second conductivity-type semiconductor layers 42 and 44, respectively. In this embodiment, the first and second electrodes 45 and 46 may be disposed on opposite surfaces of the first and second conductivity-type semiconductor layers 42 and 44 and the active layer 43 interposed between the first and second electrodes 45 and 46. A support substrate 41 may be attached to the second electrode 46 by a bonding layer 41a and may support the light emitting device 40.

The light emitting device 40 according to this embodiment may further include a connecting electrode 47 as an electrode element in association with the second electrode 46. The connecting electrode 47 may be connected to the second electrode 46 through a through hole H formed by at least partially removing the first and second conductive-type semiconductor layers 42 and 44 and the active layer 43. At least a portion of the second electrode 46 may be exposed through the through hole H and in the exposed portion, the second electrode 46 and the connecting electrode 47 may be connected to each other. The connecting electrode 47 may be formed along a sidewall of the through hole H, and an insulating layer 47a may be provided between the connecting electrode 47 and the sidewall of the through hole H in order to prevent electrical connections between the connecting electrode 47 and the active layer 43 and the first conductivity-type semiconductor layer 42.

Such an electrode structure may be further efficiently applied to a form in which the first and second conductivity-type semiconductor layers 42 and 44 are n-type and p-type nitride semiconductor layers, respectively. Since the p-type nitride semiconductor layer has a degree of contact resistance greater than that of the n-type nitride semiconductor layer, it may be difficult to obtain ohmic-contact. However, in the embodiment illustrated in FIG. 14, since the second electrode 46 is disposed over the entire surface of the support substrate 41, a contact area between the second conductivity-type semiconductor layer 44 and the second electrode 46 may be sufficiently secured, whereby ohmic-contact between the second electrode 46 and the p-type nitride semiconductor layer may be obtained.

The light emitting device 40 according to the embodiment illustrated in FIG. 18 may have a flip-chip structure in which light is emitted in a direction toward the support substrate 41. That is, the first electrode 45 and the connecting electrode 47 may be electrically connected to circuit patterns 49a of a circuit board 49 by solder bumps 48. In the case of applying the light emitting device 40 according to the embodiment illustrated in FIG. 18 to the light emitting device packages 100, 200, 300, 400, 500, 600, 700, or the like according to various embodiments as described above, the light emitting device 40 may be connected to the lead frames by the solder bumps 48.

The first electrode 45 may contain an electrode material having a higher degree of reflectance as well as ohmic-contact characteristics. The second electrode 46 and the support substrate 41 may have high light-transmissive properties. For example, the first electrode 45 may contain a material such as Ag, Ni, Al, Rh, Pd, Ir, Ru, Mg, Zn, Pt, Au or the like. The second electrode 46 may be formed of a light-transmissive metal such as Ni/Au or may be formed of a transparent conductive oxide or nitride such as ITO. The support substrate 41 may be a glass substrate or a substrate formed of a light-transmissive polymer resin.

The connecting electrode 47 may be electrically insulated from the first conductivity-type semiconductor layer 42 and the active layer 43 by the insulating layer 47a. As illustrated in FIG. 18, the insulating layer 47a may be formed along the sidewall of the through hole H. In addition, the insulating layer 47a may be formed on side surfaces of the first and second conductivity-type semiconductor layers 42 and 44 and the active layer 43 and may be provided as a passivation layer for the light emitting device 10. The insulating layer 47a may contain a silicon oxide or a silicon nitride.

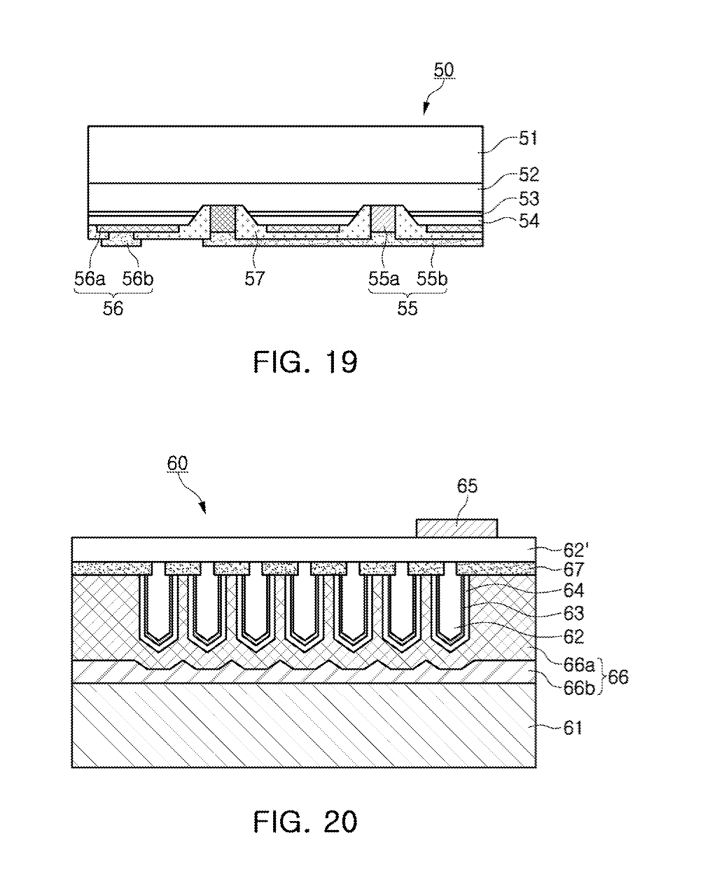

Referring to FIG. 19, a light emitting device 50 according to another embodiment is disclosed. The light emitting device 50 may include a first conductivity-type semiconductor layer 52, an active layer 53, and a second conductivity-type semiconductor layer 54 sequentially stacked on one surface of a substrate 51, and first and second electrodes 55 and 56. In addition, the light emitting device 50 may include an insulating portion 57. The first and second electrodes 55 and 56 may include contact electrodes 55a and 56a and connecting electrodes 55b and 56b, and partial regions of the contact electrodes 55a and 56a exposed by the insulating portion 57 may be connected to the connecting electrodes 55b and 56b.

The first contact electrode 55a may be provided as a conductive via penetrating through the second conductivity-type semiconductor layer 54 and the active layer 53 to be connected to the first conductivity-type semiconductor layer 52. The second contact electrode 56a may be connected to the second conductivity-type semiconductor layer 54. Multiple conductive vias may be provided in a single region of the light emitting device.

A conductive ohmic material may be deposited on the first and second conductivity-type semiconductor layers 52 and 54 to form first and second contact electrodes 55a and 56a. The first and second contact electrodes 55a and 56a may contain at least one of Ag, Al, Ni, Cr, Cu, Au, Pd, Pt, Sn, Ti, W, Rh, Ir, Ru, Mg, and Zn or an alloy material containing these materials. In addition, the second contact electrode 56a may serve to reflect light generated in the active layer 53 and emitted downwardly of the light emitting device 50.

The insulating portion 57 may have open regions through which at least portions of the first and second contact electrodes 55a and 56a are exposed, and the first and second connecting electrodes 55b and 56b may be connected to the first and second contact electrodes 55a and 56a, respectively. The insulating portion 57 may be deposited at a thickness of about 0.01 μm to about 3 μm at a temperature of about 500° C. or lower through a SiO₂ and/or SiN CVD process. The first and second electrodes 55 and 56 may be mounted on the light emitting device package in a flip-chip scheme.

The first and second electrodes 55 and 56 may be electrically isolated from each other by the insulating portion 57. Although the insulating portion 57 may be formed of any material as long as the material has electrical insulation properties, the insulating portion 57 may be preferably, formed of a material having a low light absorption rate in order to prevent a deterioration in light extraction efficiency. For example, a silicon oxide or a silicon nitride such as SiO₂, SiOₓN_{y}, SiₓN_{y} or the like may be used. A light reflecting structure may be formed by dispersing light reflective fillers in a light-transmissive material.

The substrate 51 may have first and second surfaces opposed to each other. An unevenness structure may be formed on at least one of the first and second surfaces. The unevenness structure formed on one surface of the substrate 51 may be formed by etching a portion of the substrate 51 and may be formed of the same material as that of the substrate 51, or may be configured of a heteromaterial different from that of the substrate 51. For example, an unevenness structure may be formed on an interface between the substrate 51 and the first conductivity-type semiconductor layer 52, such that a path of light emitted from the active layer 53 may be variously formed. Thus, a ratio at which light is absorbed in the interior of a semiconductor layer may be reduced and a light scattering ratio may be increased to thereby enhance light extraction efficiency. In addition, a buffer layer may be provided between the substrate 51 and the first conductivity-type semiconductor layer 52.

Referring to FIG. 20, a light emitting device 60 according to another embodiment may be a light emitting device 60 having a light emitting nanostructure. The light emitting device 60 may include a base layer 62′ containing a first conductivity-type semiconductor material, a mask layer 67 provided on the base layer 62′ and providing multiple openings, and nanocores 62 formed in the openings of the mask layer 67. On the nanocores 62, active layers 63 and second conductivity-type semiconductor layers 64 may be provided. The nanocores 62, the active layers 63 and the second conductivity-type semiconductor layers 64 may provide the light emitting nanostructure.

A second contact electrode 66a may be prepared on the second conductivity-type semiconductor layers 64, and a second connecting electrode 66b may be provided on one surface of the second contact electrode 66a. The second contact electrode 66a and the second connecting electrode 66b may be provided as a second electrode 66. A support substrate 61 may be attached to one surface of the second electrode 66 and may be a conductive substrate or an insulating substrate. In the case that the support substrate 61 has conductivity, the support substrate 61 may be directly mounted on the lead frames of the light emitting device package 100, 200, 300, 400, 500, 600, 700m or the like. A first electrode 65 may be provided on the base layer 62′ containing a first conductivity-type semiconductor material. The first electrode 65 may be connected to the lead frames of the light emitting device package 100, 200, 300, 400, 500, 600, 700, or the like by a wire or the like.

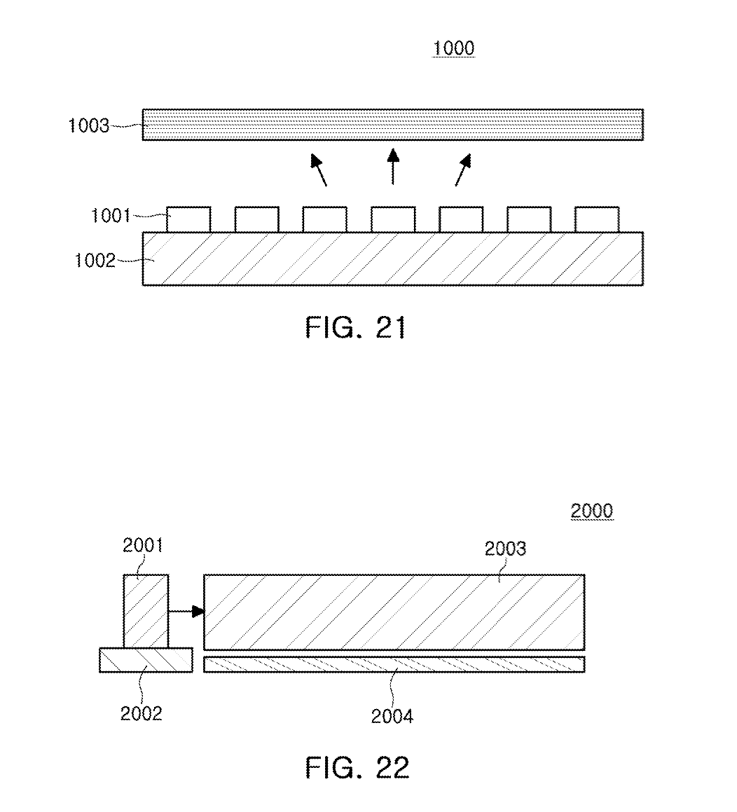

FIG. 21 and FIG. 22 are views illustrating examples of backlight units including a light emitting device package according to an embodiment.

Referring to FIG. 21, a backlight unit 1000 may include a substrate 1002, a light source 1001 mounted on the substrate 1002, and at least one optical sheet 1003 disposed thereabove. The optical sheet 1003 may include a diffusion sheet, a prism sheet and the like, and the light source 1001 may include the light emitting device package as described above.

The light source 1001 in the backlight unit 1000 of FIG. 21 may be configured to emit light toward a liquid crystal display (LCD) device disposed thereabove. On the other hand, a light source 2001 mounted on a substrate 2002 in a backlight unit 2000 according to another embodiment illustrated in FIG. 22 may be configured to emit light laterally, and the emitted light may be incident on a light guide plate 2003 and may be converted into the form of a surface light source. The light having passed through the light guide plate 2003 may be emitted upwardly and a reflective layer 2004 may be disposed below a bottom surface of the light guide plate 2003 in order to improve light extraction efficiency.

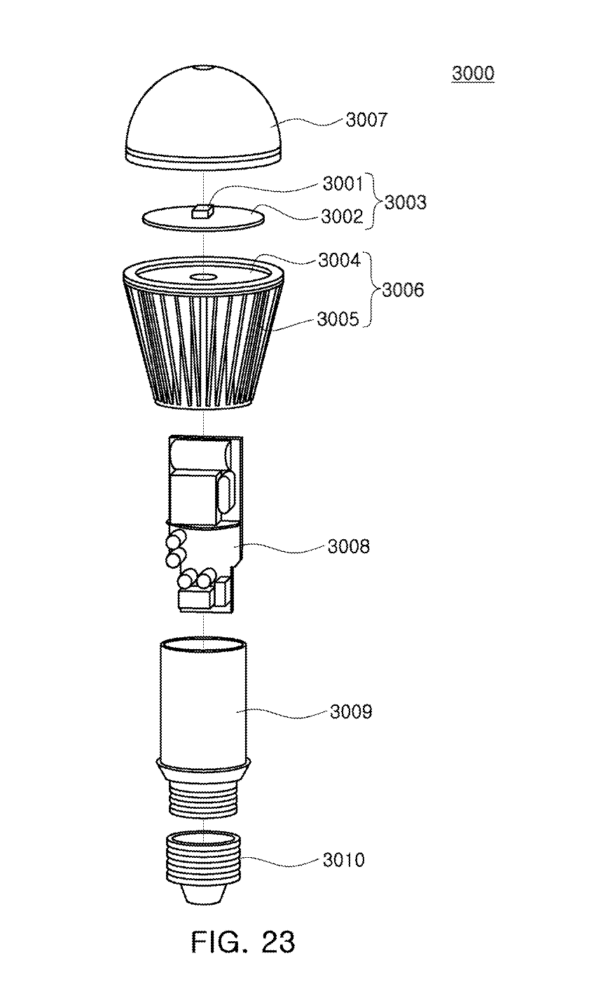

FIG. 23 is a view illustrating an example of a lighting device including a light emitting device package according to an embodiment.

A lighting device 3000 illustrated in FIG. 23 is exemplified as a bulb-type lamp, and may include a light emitting module 3003, a driving unit 3008, an external connector unit 3010 and the like.

In addition, exterior structures such as an external housing 3006, an internal housing 3009, a cover unit 3007 and the like may be further included in the lighting device 3000. The light emitting module 3003 may include a light source 3001 that may be the aforementioned semiconductor light emitting device or a package including the semiconductor light emitting device, and a circuit board 3002 having the light source 3001 mounted thereon. The light source 3001 may include the light emitting device package as described above. The embodiment illustrates a case in which a single light source 3001 is mounted on the circuit board 3002; however, if necessary, multiple light sources may be mounted thereon.

The external housing 3006 may serve as a heat radiating part, and include a heat sink plate 3004 in direct contact with the light emitting module 3003 to improve the dissipation of heat and heat radiating fins 3005 covering a lateral surface of the lighting device 3000. The cover unit 3007 may be disposed above the light emitting module 3003 and may have a convex lens shape. The driving unit 3008 may be mounted within the internal housing 3009 and may be connected to the external connector unit 3010, such as a socket structure, to receive power from an external power source.

In addition, the driving unit 3008 may be configured to convert the received power into a current source appropriate for driving the light source 3001 of the light emitting module 3003 and supply the converted current source thereto. For example, the driving unit 3008 may be configured of an AC-DC converter, a rectifying circuit part, or the like.

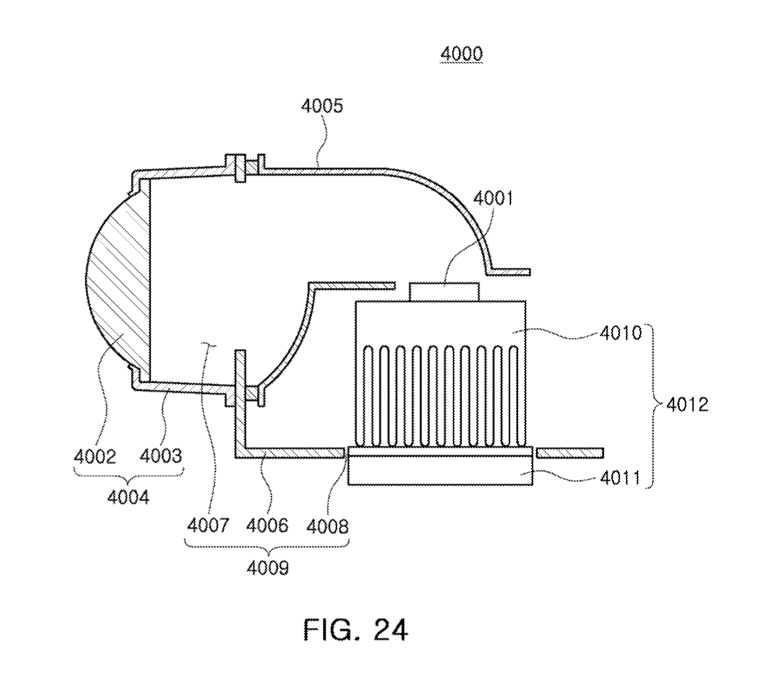

FIG. 24 is a view illustrating an example of a headlamp including a light emitting device package according to an embodiment.

Referring to FIG. 24, a headlamp 4000 used as a vehicle lighting element or the like may include a light source 4001, a reflective unit 4005 and a lens cover unit 4004. The lens cover unit 4004 may include a hollow guide part 4003 and a lens 4002. The light source 4001 may include the aforementioned semiconductor light emitting device or a package including the semiconductor light emitting device.

The headlamp 4000 may further include a heat radiating unit 4012 dissipating heat generated by the light source 4001 outwardly. The heat radiating unit 4012 may include a heat sink 4010 and a cooling fan 4011 in order to effectively dissipate heat. In addition, the headlamp 4000 may further include a housing 4009 allowing the heat radiating unit 4012 and the reflective unit 4005 to be fixed thereto and supported thereby. The housing 4009 may include a central hole 4008 to which the heat radiating unit 4012 is coupled to be mounted therein, the central hole 4008 being formed in one surface of the housing 4009.

The other surface of the housing 4009 integrally connected to and bent in a direction perpendicular to the one surface of the housing 4009 may be provided with a forward hole 4007 such that the reflective unit 4005 may be disposed above the light source 4001. Accordingly, a forward side may be opened by the reflective unit 4005 and the reflective unit 4005 may be fixed to the housing 4009 such that the opened forward side corresponds to the forward hole 4007, whereby light reflected by the reflective unit 4005 may pass through the forward hole 4007 to thereby be emitted outwardly.

An embodiment includes a light emitting device package having high reliability by providing a support part able to disperse stress occurring in the exterior or the interior of the light emitting device package, in a package body.

In an embodiment, a light emitting device package may include a package body having a mounting space, first and second lead frames provided in the package body, a light emitting device disposed on the first and second lead frames within the mounting space and electrically connected to the first and second lead frames, and a support part disposed below the first and second lead frames and having a region overlapping with at least a portion of a space formed between the first and second lead frames, the support part containing a material different from that of the package body.

In an embodiment, a light emitting device package may include a package body, a pair of lead frames provided in the package body, and a light emitting device disposed on the pair of lead frames and electrically connected to the pair of lead frames, wherein the package body includes a support part provided within the package body and having a region overlapping with at least a portion of a space formed between the pair of lead frames, the support part containing a material different from that of the package body.

In an embodiment, a light emitting device package may include a package body, a pair of lead frames provided in the package body and electrically isolated from each other, and a light emitting device disposed on the pair of lead frames and electrically connected to the pair of lead frames, wherein the pair of lead frames have a receiving space provided to be adjacent to a space formed between the pair of lead frames, and a support part disposed within the receiving space.

As set forth above, according to various embodiments, a support part having a region overlapping with at least a portion of a space between first and second lead frames disposed in a package body may be disposed below the first and second lead frames. Thus, force applied from the interior or the exterior of a light emitting device package may not be concentrated on the space between first and second lead frames and may be dispersed by the support part, such that reliability of the light emitting device package may be improved.

While particular embodiments have been shown and described above, it will be apparent to those skilled in the art that modifications and variations could be made without departing from the scope of the invention as defined by the appended claims.

What is claimed is:

1. A light emitting device package comprising:
a package body;
first and second lead frames; and
a support part disposed below the first and second lead frames and having a region overlapping with at least a portion of a space formed between the first and second lead frames, the support part containing a material different from that of the package body.

2. The light emitting device package of claim 1,
further comprising a light emitting device;
wherein:
the package body includes a mounting space; and
the light emitting device is disposed on the first and second lead frames within the mounting space and electrically connected to the first and second lead frames.

3. The light emitting device package of claim 2, further comprising: a molding resin part filling the mounting space.

4. The light emitting device package of claim 3, wherein the molding resin part includes a wavelength conversion material.

5. The light emitting device package of claim 1, wherein the first and second lead frames are disposed in the package body.

6. The light emitting device package of claim 1, wherein the support part has a higher level of strength than that of the package body.

7. The light emitting device package of claim 1, wherein the support part is bonded to lower surfaces of the first and second lead frames.

8. The light emitting device package of claim 7, wherein the support part is attached to the lower surfaces of at least a portion of the first and second lead frames by an electrically insulating adhesive layer.

9. The light emitting device package of claim 7, wherein the support part is bonded to the at least a portion of the first and second lead frames by a fastener.

10. The light emitting device package of claim 7, wherein the support part is disposed within a receiving space within the first and second lead frames.

11. The light emitting device package of claim 10, wherein the support part is bonded to the first and second lead frames within the receiving space by an electrically insulating adhesive layer.

12. The light emitting device package of claim 1, wherein the support part is attached to a lower surface of the package body.

13. The light emitting device package of claim 1, wherein the support part has a plurality of regions separated from each other.

14. The light emitting device package of claim 1, wherein the support part has a coefficient of thermal expansion equal to or lower than that of the first and second lead frames.

15. A light emitting device package of claim 1, wherein
the first and second lead frames are disposed in the package body; and
the support part is disposed in the package body.

16. A light emitting device package comprising:
a package body;
a pair of lead frames disposed in the package body and electrically isolated from each other; and
a support part;
wherein the pair of lead frames have a receiving space adjacent to a space formed between the pair of lead frames, and the support part is disposed within the receiving space.

17. The light emitting device package of claim 16, wherein the support part is fastened to the pair of lead frames within the receiving space by an electrically insulating adhesive layer.

18. The light emitting device package of claim 16, wherein the support part has a coefficient of thermal expansion equal to or lower than that of the pair of lead frames.

19. A light emitting device package comprising:
a package body;
first and second lead frames disposed in the package body and electrically isolated from each other;
a light emitting device disposed on the first and second lead frames; and
a support part disposed on a side of the first and second lead frames opposite to the light emitting device, extending across a separation space between the first and second lead frames, and containing a material different from that of the package body.

20. The light emitting device package of claim 19, wherein the support part has a coefficient of thermal expansion lower than that of the first and second lead frames.
